(19) United States
(12) Patent Application Publication
(10) Pub. No.: US 2012/0049310 A1
(43) Pub. Date: Mar. 1, 2012

(54) THIN FILM PHOTOELECTRIC CONVERSION MODULE AND FABRICATION METHOD OF THE SAME

(75) Inventors: Jia-Wei MA, New Taipei City (TW); Chung-Pui Chan, Hong Kong (HK); Tze-Kin Yuen, Hong Kong (HK); Hsieh-Hsin Yeh, New Taipei City (TW); Chen-Pang Fu, New Taipei City (TW); Hi-Ki Lam, Hong Kong (HK); Wa-Sze Tsang, Hong Kong (HK); Yang-Yang Zhou, Hong Kong (HK); Chi-Chiu Leung, Hong Kong (HK)

(73) Assignee: Du Pont Apollo Limited, Hong Kong (HK)

(21) Appl. No.: 13/220,696

(22) Filed: Aug. 30, 2011

Related U.S. Application Data
(60) Provisional application No. 61/378,969, filed on Sep. 1, 2010.

(51) Int. Cl. H01L 31/0216; H01L 31/18

(52) U.S. Cl. 257/435; 438/80; 257/E31.119

(57) ABSTRACT

A thin film photoelectric conversion module is provided. The thin film photoelectric conversion module includes a substrate and a plurality of photoelectric conversion cells formed on the substrate and connected to each other in series to form a series-connected array. The thin film photoelectric conversion module further comprises a plurality of first electrode rows extending along a current flow direction and a resistive material electrically connected to adjacent two of the first electrode rows, wherein the resistive material has an electrical resistivity no less than 10⁻⁹ ohm-cm, wherein when the resistive material is a material different from that of the first electrode rows, the resistive material makes adjacent two of the first electrode rows at least partially connected, and when the resistive material is a material the same as that of the first electrode rows, the resistive material makes adjacent two of the first electrode rows partially connected.

### RELATED APPLICATIONS

This application claims priority to U.S. Provisional Application Ser. No. 61/378,969, filed Sep. 1, 2010, which is herein incorporated by reference.

### BACKGROUND

1. Technical Field

The present disclosure relates to a photoelectric conversion apparatus. More particularly, the present disclosure relates to a thin film photoelectric conversion module and a fabrication method of the same.

2. Description of Related Art

A solar cell is a device that converts the energy of sunlight directly into electricity by the photovoltaic effect. In general, a thin film photoelectric conversion module comprises a plurality of thin film photoelectric conversion cells connected to each other in series.

When a stain, such as a leaf or a bird dropping, is attached to the light-receiving surface of parts of the thin film photoelectric conversion module, the light to the particular cell is partially or entirely intercepted by the stain so as to decrease the photoelectric motive force. The decreased photoelectric motive force acts as a diode connected in series in the reverse direction to the direction of the power generation. As a result, the light-intercepted cell exhibits a very high resistance, leading to the marked reduction in the output of the entire module. Further, the current doesn't flow uniformly through the cell so as to bring about a local heating called a hot spot phenomenon.

Accordingly, what is needed is a thin film photoelectric conversion module and a fabrication method of the same that is able to reduce the effect of the hot spot phenomenon. The present disclosure addresses such a need.

### SUMMARY

An aspect of the present disclosure is to provide a thin film photoelectric conversion module. The thin film photoelectric conversion module includes a substrate and a plurality of photoelectric conversion cells formed on the substrate and connected to each other in series to form a series-connected array. The module further comprises a plurality of first electrode rows extending along a current flow direction and a resistive material electrically connected to adjacent two of the first electrode rows. The resistive material has an electrical resistivity no less than 10⁻⁹ ohm-cm, wherein when the resistive material is a material different from that of the first electrode rows, the resistive material makes adjacent two of the first electrode rows at least partially connected, and when the resistive material is a material the same as that of the first electrode rows, the resistive material makes adjacent two of the first electrode rows partially connected.

Another aspect of the present disclosure is to provide a thin film photoelectric conversion module which comprises a substrate, a first electrode layer, at least one photoelectric conversion layer and a second electrode layer. The first electrode layer formed on the substrate comprises a plurality of first electrode rows, a resistive material and a plurality of first grooves. The plurality of first electrode rows extend along a current flow direction. The resistive material is electrically connected to adjacent two of the first electrode rows, wherein the resistive material has an electrical resistivity no less than 10⁻⁹ ohm-cm. The plurality of first grooves separates the first electrode layer into a plurality of first electrode columns along a direction which crosses the current flow direction. The photoelectric conversion layer is deposited on the first electrode layer, wherein the photoelectric conversion layer comprises a plurality of second grooves each formed next to one of the first grooves. The second electrode layer is deposited on the photoelectric conversion layer, wherein the second electrode layer comprises a plurality of third grooves penetrating through the second electrode layer and each of the third grooves is formed next to one of the second grooves, wherein when the resistive material is a material different from that of the first electrode rows, the resistive material makes adjacent two of the first electrode rows at least partially connected, and when the resistive material is a material the same as that of the first electrode rows, the resistive material makes adjacent two of the first electrode rows partially connected.

Yet another aspect of the present disclosure is to provide a method to fabricate a thin film photoelectric conversion module. The thin film photoelectric conversion module includes a substrate and a plurality of photoelectric conversion cells formed on the substrate and connected to each other in series to form a series-connected array. The method comprises the steps as follows. A plurality of first traversing grooves are defined in a first electrode layer of the series-connected array along a current flow direction, so as to separate the first electrode layer into a plurality of first electrode rows. A resistive material is formed between adjacent two of the plurality of first electrode rows, wherein the resistive material has an electrical resistivity no less than 10⁻⁹ ohm-cm.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a top view of a thin film photoelectric conversion module in an embodiment of the present disclosure;

FIG. 1B is a cross-sectional view of part of the thin film photoelectric conversion module from the direction H1 in FIG. 1A;

FIG. 10 and FIG. 1D are two cross-sectional view of part of the thin film photoelectric conversion module from the direction H1 in different embodiments;

FIG. 2A to FIG. 2C are partial top views of the thin film photoelectric conversion module in different embodiments of the present disclosure;

FIG. 3A to FIG. 3D are the partial cross-sectional views of the thin film photoelectric conversion module in FIG. 2A from the directions of H1, H2, V1 and V2 respectively;

FIG. 4A to FIG. 4D are the partial cross-sectional views of the thin film photoelectric conversion module in FIG. 2B from the directions of H1, H2, V1 and V2 respectively;

FIG. 5A to FIG. 5D are the partial cross-sectional views of the thin film photoelectric conversion module in FIG. 2C from the directions of H1, H2, V1 and V2 respectively;

FIG. 6 is a flow chart of the fabricating method to fabricate a thin film photoelectric conversion module in an embodiment of the present disclosure;

FIG. 7A to FIG. 7D illustrate each step of the manufacturing process of the thin film photoelectric conversion module through the top views; and

FIG. 8 is another flow chart of the fabricating method to fabricate a thin film photoelectric conversion module in another embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

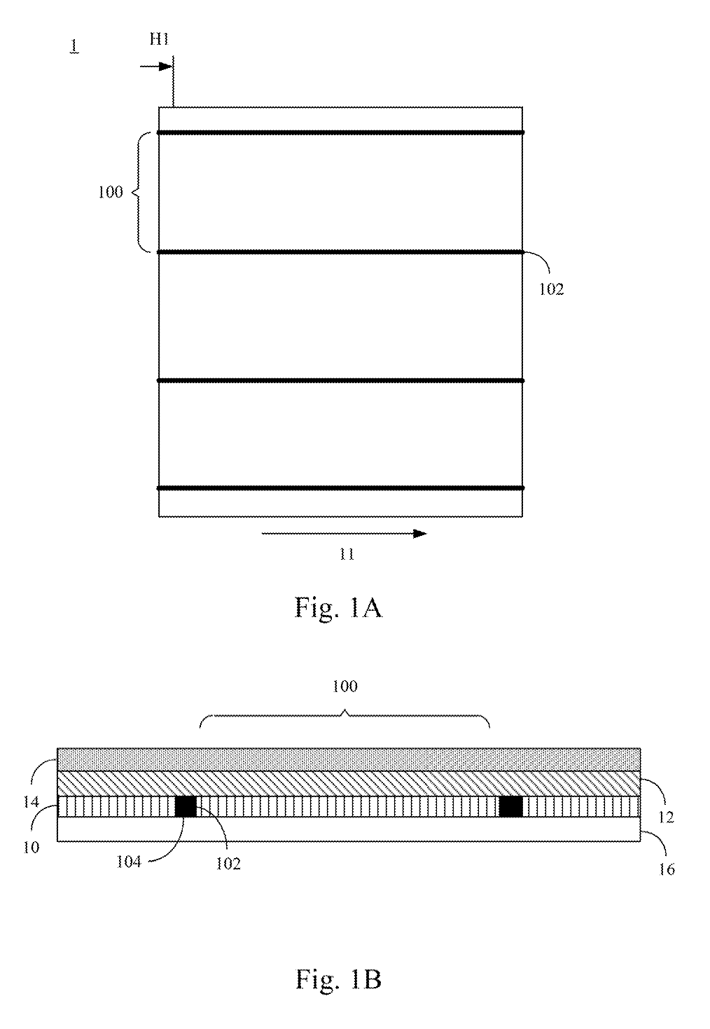

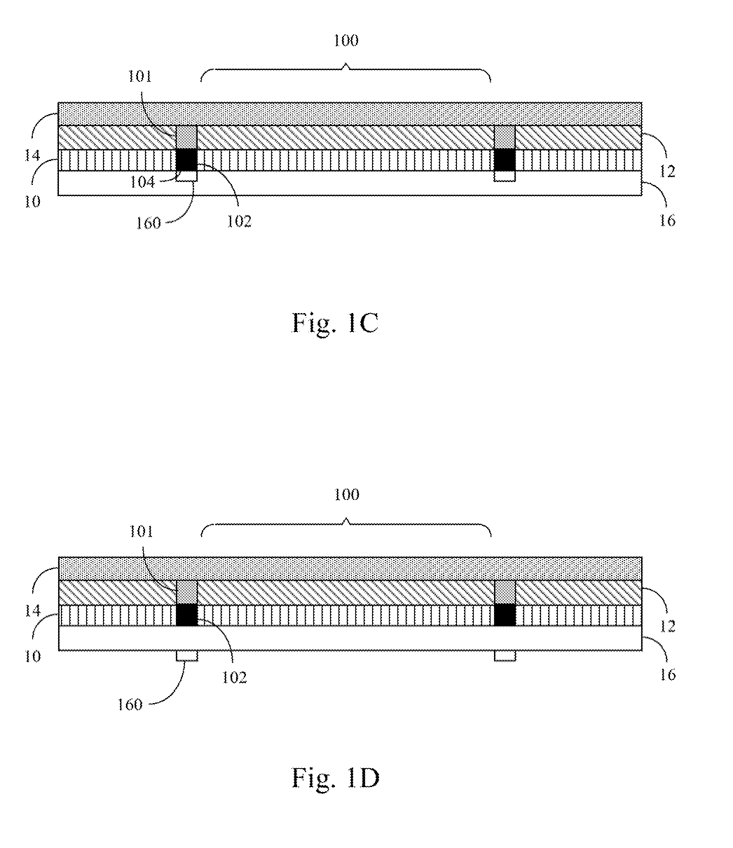

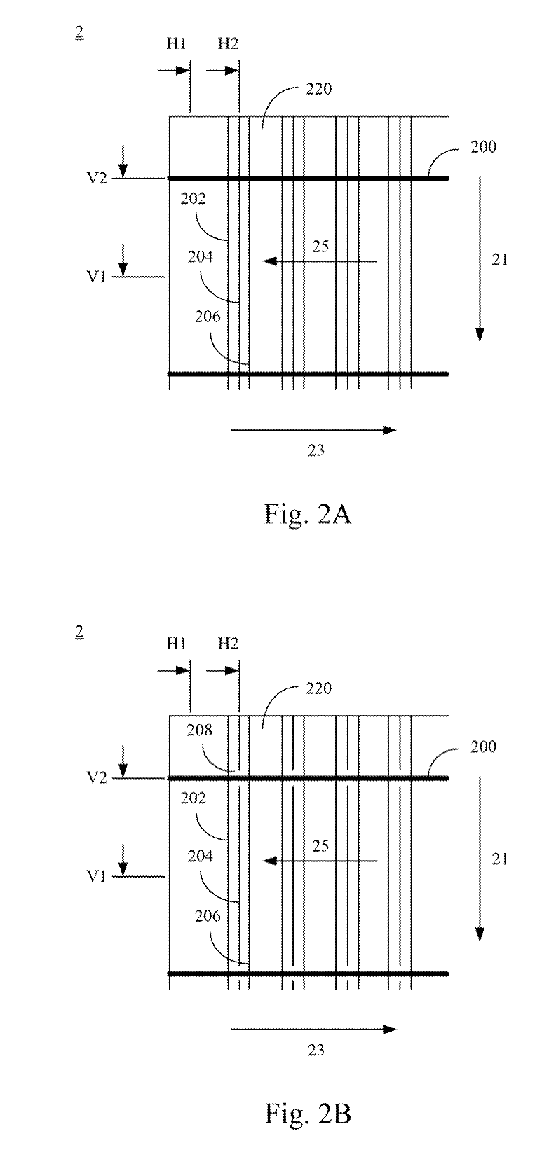

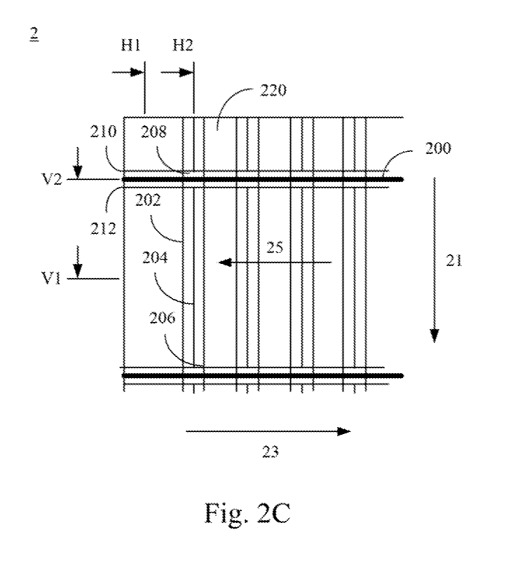

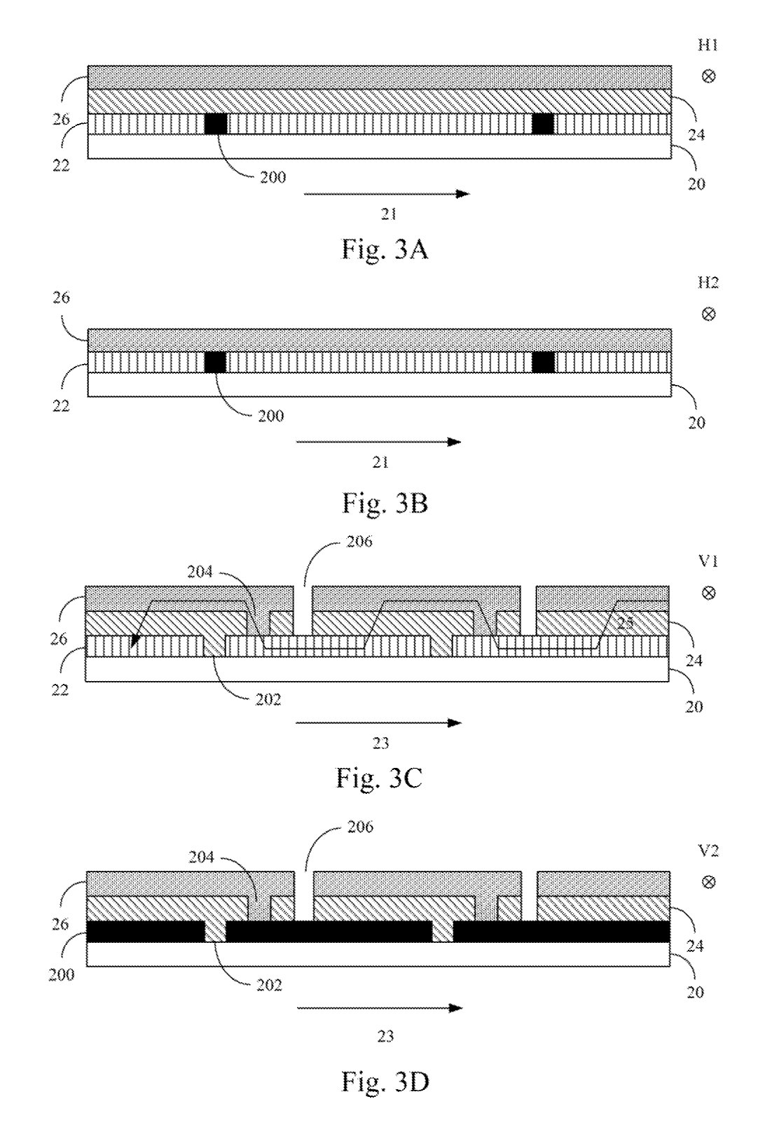

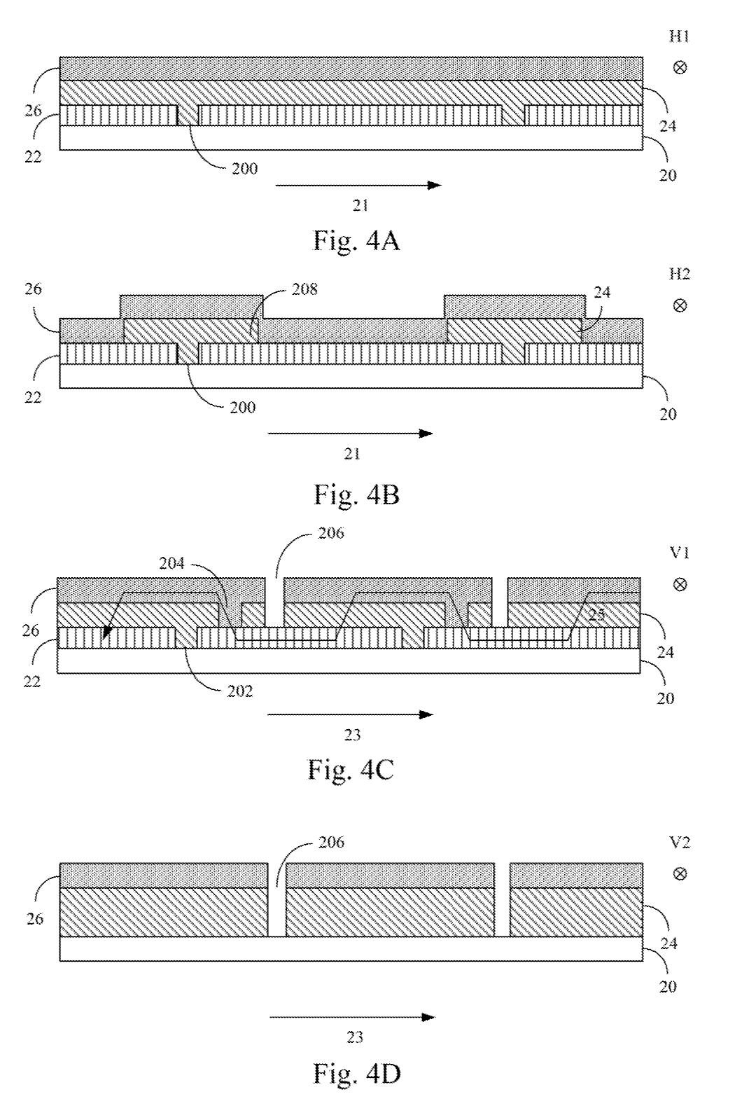

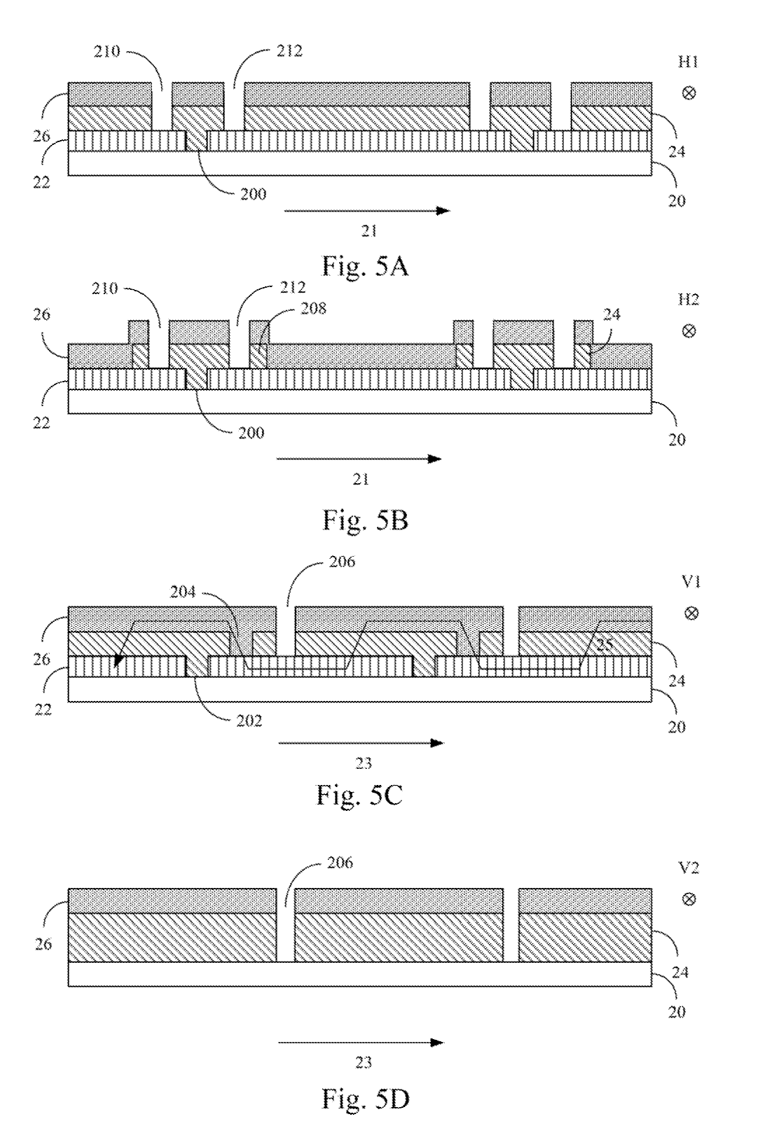

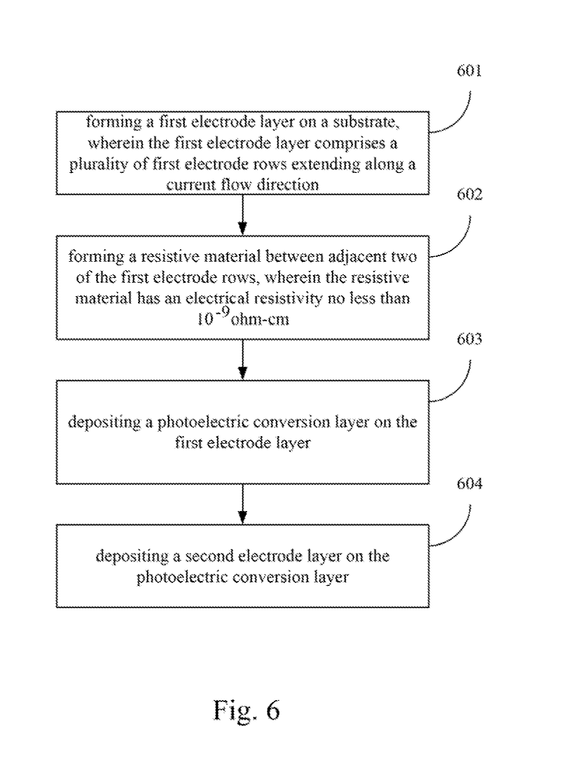

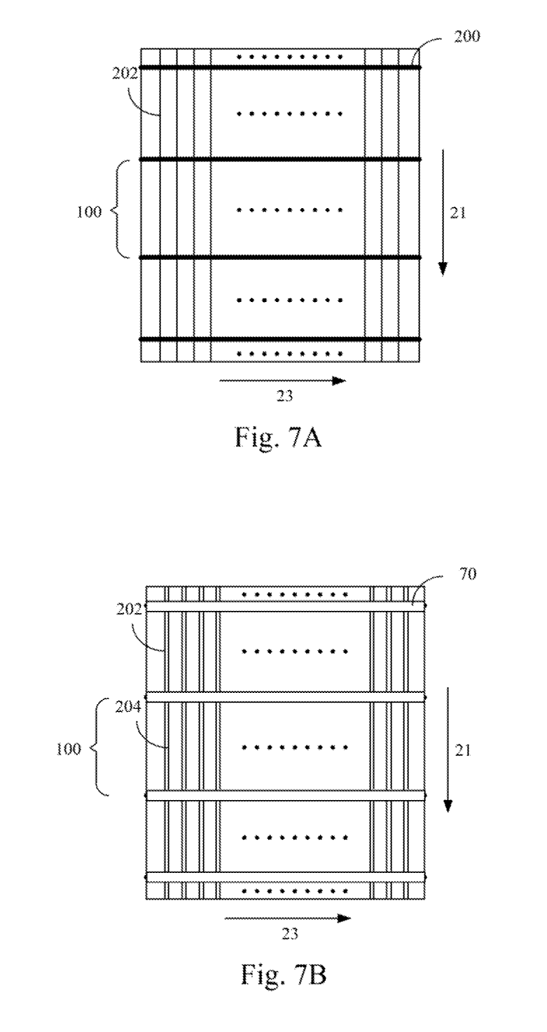

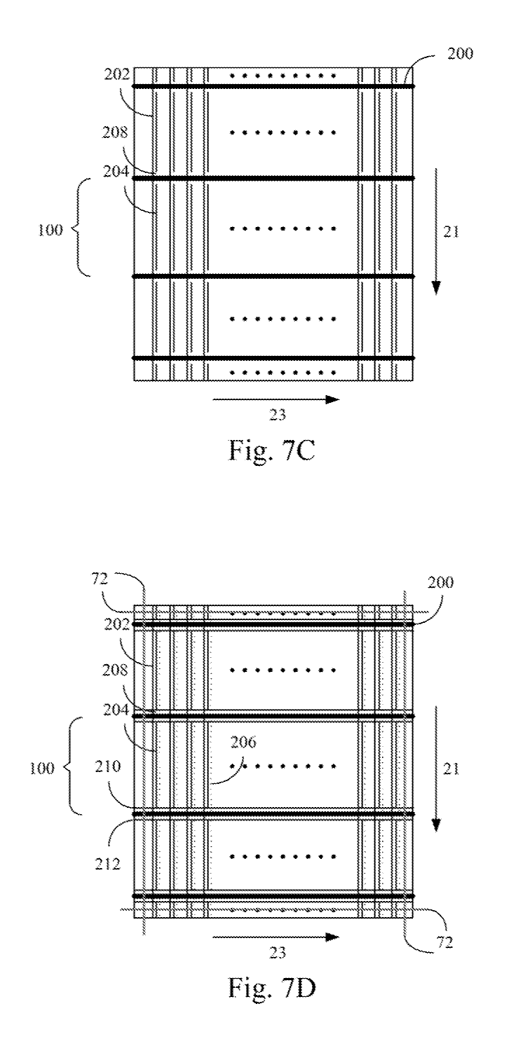

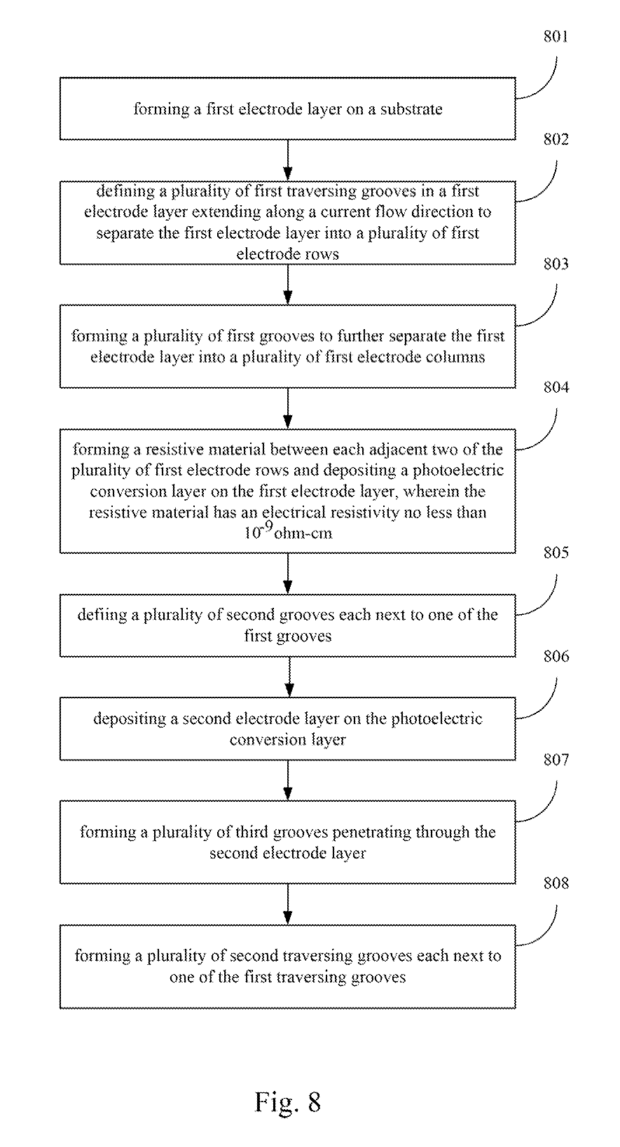

Please refer to FIG. 1A and FIG. 1B at the same time. FIG. 1A is a top view of a thin film photoelectric conversion module 1 in an embodiment of the present disclosure, and FIG. 1B is a cross-sectional view of part of the thin film photoelectric conversion module 1 from the direction H1.

The thin film photoelectric conversion module 1 comprises a substrate 16, a first electrode layer 10, a photoelectric conversion layer 12 and a second electrode layer 14 sequentially. The first electrode layer 10 comprises a plurality of first electrode rows 100 and a resistive material 102, wherein in an embodiment the first electrode layer 10 is a front electrode. The first electrode rows 100 are substantially physically parallel to each other along a current flow direction, in which means a horizontal direction 11 shown in FIG. 1A. The current flow direction is a direction that the current flows in the thin film photoelectric conversion module 1 when it is in operation.

The resistive material 102 is electrically connected to adjacent two of the first electrode rows 100, wherein the resistive material 102 has an electrical resistivity no less than 10⁻⁹ ohm-cm. In an embodiment the second electrode layer 14 is a back electrode. One of the first electrode layer 10 and the second electrode layer 14 can be a transparent conducting layer to allow the light passing through, and the other one can be either a transparent conducting layer or a metal layer according to designs. The substrate 16 next to the first electrode layer 10 can be made of a transparent material, such as glass. Thus, the current in the thin film photoelectric conversion module 1 of this invention can distribute in different rows, thereby avoiding the overheat condition.

Since the resistive material 102 has the electrical resistivity no less than 10⁻⁹ ohm-cm, adjacent two of the first electrode rows 100 are still electrically connected so that the first electrode rows 100 are not electrically isolated. In other words, the first electrode rows 100 are not connected in an electrically parallel form. Thus, the currents in different first electrode rows 100 are not easy to flow to other first electrode rows 100 through the resistive material 102 to make sure the current distributing mechanism is maintained. Thus, the effect of the hot spot phenomenon is greatly reduced.

In an embodiment, the resistive material 102 is formed in a plurality of first traversing grooves 104 of the first electrode layer 10. In an embodiment, when the resistive material 102 is a material different from the first electrodes 10, the resistive material 102 makes adjacent two of the first electrode rows 100 at least partially connected, i.e. the resistive material 102 can be partially or totally filled in the first traversing grooves 104. When the resistive material 102 is a material the same as the first electrode, the resistive material 102 makes adjacent two of the first electrode rows partially connected only. Alternatively, parts of the material of the photoelectric conversion layer 12 are filled in the first traversing grooves 104 to form the resistive material 102. In an embodiment, a part of the material of the second electrode layer 14 may be filled in the first traversing grooves 104 as well.

Please refer to FIG. 1C. In yet another embodiment, the substrate 16 of the thin film photoelectric conversion module 1 is a transparent substrate. In an embodiment, the substrate 16 is made of glass. The substrate 16 further comprises a plurality of opaque materials 160 each deposited between the substrate 16 and the first electrode layer 10, which are used to block the sunlight transmitting into the module 1, so as to make the corresponding positions of the photoelectric conversion layer 12 underneath become high resistance structures 101. The position of each of the opaque materials 160 can be in alignment with one of the first traversing grooves 104 shown in FIG. 1B. Therefore, the current distributing mechanism in different rows further reinforces due to the presence of the opaque materials 160. In other embodiments, the opaque materials 160 can be deposited on the side of the substrate 16 opposite to the first electrode layer 10, as shown in FIG. 1D.

Please refer to FIG. 2A and FIG. 3A to FIG. 3D at the same time. FIG. 2A is a partial top view of a thin film photoelectric conversion module 2 in an embodiment of the present disclosure. FIG. 3A to FIG. 3D are the partial cross-sectional views of the thin film photoelectric conversion module 2 in FIG. 2A from the directions of H1, H2, V1 and V2 respectively.

Refer to FIG. 2A, FIG. 3C and FIG. 3D, the thin film photoelectric conversion module 2 in comprises a substrate 20, a first electrode layer 22, a photoelectric conversion layer 24 and a second electrode layer 26 sequentially. The first electrode layer 22 comprises a plurality of first grooves 202 separating the first electrode layer 22 into a plurality of first electrode columns along a direction 21 which crosses the current flow direction 23.

The first electrode layer 22 further comprises a plurality of first traversing grooves 200 each traversing the plurality of first electrode columns to separate the first electrode layer 22 into a plurality of first electrode rows, as shown in FIG. 2A, FIG. 3A and FIG. 3B. In other words, the first traversing grooves 200 form the borders of the first electrode rows. In an embodiment, the first traversing grooves 200 and the first grooves 202 are substantially perpendicular to each other. The term “substantially perpendicular” used herein means that the first traversing grooves 200 and the first grooves 202 may have an angle slightly different from 90 degrees between them. It's noticed that in the first traversing grooves 200, a resistive material is filled in to make adjacent two of the first electrode rows electrically connected, as shown in FIG. 3A, FIG. 3B and FIG. 3D.

The photoelectric conversion layer 24 comprises a plurality of second grooves 204 each formed substantially parallel and next to one of the first grooves 202. The second electrode layer 26 and the photoelectric conversion layer 24 comprise a plurality of third grooves 206 penetrating through therein, wherein each of the third grooves 206 is formed substantially parallel and next to one of the second grooves 204.

It's noticed that when the second grooves 204 are formed by a laser scribing process, the resistive material is well selected according to the wavelength of the laser such that the resistive material at intersections of the first traversing grooves 200 and the second grooves 204 will not be removed. If a chemical etching process or a mechanical separating process is used for forming the second grooves 204, the depth of the etching is well controlled such that the resistive material at intersections of the first traversing grooves 200 and the second grooves 204 will not be removed.

Please refer to FIG. 2B and FIG. 4A to FIG. 4D at the same time. FIG. 2B is a partial top view of a thin film photoelectric conversion module 2 in another embodiment of the present disclosure. FIG. 4A to FIG. 4D are the partial cross-sectional views of the thin film photoelectric conversion module 2 in FIG. 2B from the directions of H1, H2, V1 and V2 respectively.

It's noticed that the resistive material filled in the first traversing grooves 200 is a part of the photoelectric conversion layer 24. Thus, the difference between the thin film photoelectric conversion module 2 in FIG. 2B and FIG. 2A is that the second grooves 204 of the thin film photoelectric conversion module 2 in FIG. 2B is discontinuous. In other words, each of the second grooves 204 in FIG. 2B comprises a plurality non-groove parts 208, as shown in FIG. 2B.

The non-groove parts 208 are formed by placing masks along the first traversing grooves 200 before the formation of the second grooves 204. Therefore, when a laser-scribing process or a chemical etching process is used to form the second grooves 204, for example, the masks prevents the material underneath from being removed by the laser-scribing process or the chemical etching process, if the material underneath is able to absorb the energy of the laser or is able to be etched by the etchant. In an embodiment, when the laser-scribing process is used, the material of the substrate 20 and the first electrode layer 22 can be selected such that they will not absorb the energy of the laser used to form the second grooves 204. Thus, the laser can be performed whether on the photoelectric conversion layer 24 or on the substrate 20 to form the second grooves 204. However, the masks have to be placed in the corresponding side that the laser is performed to block the laser.

In another embodiment, the non-groove parts 208 can be also formed by a discontinuous separating process without using masks. For example, when the laser-scribing process is used, the laser scribing is performed several times instead to form the sub-grooves between each two of the non-groove parts 208. This means the discontinuous scribed grooves can be created by well controlling laser on/off switch or using a shutter to shade from laser beam when needed. In still another embodiment, the chemical etching process and the mechanical separating process can also be applied discontinuously as described above if they are well controlled.

As shown in FIG. 4D, the first traversing groove 200 is filled with the material of the photoelectric conversion layer 24.

Further, the non-groove parts 208 separate the first electrode layer 22 on the borders of each row to make the current in one of the rows not easy to flow to the other rows. Therefore, the effect of the hot spot phenomenon is greatly reduced.

Please refer to FIG. 2C and FIG. 5A to FIG. 5D at the same time. FIG. 2C is a partial top view of a thin film photoelectric conversion module 2 in yet another embodiment of the present disclosure. FIG. 5A to FIG. 5D are the partial cross-sectional views of the thin film photoelectric conversion module 2 in FIG. 2C from the directions of H1, H2, V1 and V2 respectively.

In the present embodiment, the second electrode layer 26 and the photoelectric conversion layer 24 further comprise a plurality of second traversing grooves 210 and 212 penetrating through the second electrode layer 26 and the photoelectric conversion layer 24 as shown in FIG. 2C, FIG. 5A and FIG. 5B, wherein each two of the second traversing grooves 210 and 212 are formed substantially parallel, next to and on the opposite side of one of the first traversing grooves 200. In an embodiment, the second traversing grooves 210 and 212 can penetrate through the second electrode layer 26 only.

Consequently, the second electrode layer 26 is physically and electrically separated into a parallel form by the second traversing grooves 210 and 212. In the previous embodiment, when hot spot phenomenon occurs, the current in one of the rows is still possible to flow to the other rows rapidly through the connected second electrode layer 26. In the present embodiment, due to the separation in the horizontal direction of the second electrode layer 26, when the hot spot phenomenon occurs on the specific row of the thin film photoelectric conversion module 2, the current flows in other rows of the thin film photoelectric conversion module 2 will not flow to the specific area through the second electrode layer 26. Therefore, the current flow generated by the thin film photoelectric conversion module 2 can be well separated.

In an embodiment, only one of the second traversing grooves 210 and 212 has to be formed next to the first traversing grooves 200 to separate the second electrode layer 26 into the parallel form. Further, it's noticed that the second traversing grooves 210 and 212 can be adapted in the structures depicted in FIG. 1A and FIG. 2A as well.

Please refer to FIG. 6. FIG. 6 is a flow chart of the fabricating method to fabricate a thin film photoelectric conversion module, as the thin film photoelectric conversion module 1 depicted in FIG. 1A and FIG. 1B in an embodiment of the present disclosure. The fabricating method comprises the following steps.

In step 601, a first electrode layer 10 is formed on a substrate, wherein the first electrode layer 10 comprises a plurality of first electrode rows extending along a current flow direction. Then in step 602, a resistive material 102 is formed between adjacent two of the plurality of first electrode rows 100, wherein the resistive material 102 has an electrical resistivity no less than 10⁻⁹ ohm-cm. In step 603, a photoelectric conversion layer 12 is deposited on the first electrode layer 10. A second electrode layer 14 is further deposited on the photoelectric conversion layer 12 in step 604.

Please refer to FIG. 7A to FIG. 7D and FIG. 8 at the same time. FIG. 7A to FIG. 7D illustrate each step of the manufacturing process of the thin film photoelectric conversion module through the top views. However, the layers such as the substrate, the first electrode layer, the photoelectric conversion layer and the second electrode layer are not specifically labeled in FIG. 7A to FIG. 7D. FIG. 8 is the flow chart of the fabricating method to fabricate a thin film photoelectric conversion module. The fabricating method comprises the following steps.

In step 801, the first electrode layer is formed on the substrate in FIG. 7A. In step 802, a plurality of first traversing grooves 200 are defined in a first electrode layer 10 extending along a current flow direction by a separating process, such as but not limited to laser-scribing process, a chemical etching process or by a mechanical separating process, so as to separate the first electrode layer into a plurality of first electrode rows 100.

Further according to FIG. 7A, a plurality of first grooves 202 are defined to further separate the first electrode layer 22 into a plurality of first electrode columns along a vertical direction 21 in step 803. In one embodiment, step 803 can be performed prior to step 802.

According to FIG. 7B, a resistive material is formed between each adjacent two of the first electrode rows and a photoelectric conversion layer 24 is deposited on the first electrode layer 22 in step 804. It's noticed that in an embodiment, the resistive material can be a material of the photoelectric conversion layer 24. In FIG. 7B, a plurality of masks 70 are placed on the photoelectric conversion layer 24 overlapping the borders of the first electrode rows, i.e. the first traversing grooves 100. In other embodiments, when the resistive material will not react with the etching process or the laser scribing process, the masks 70 are not necessary.

According to FIG. 7C, in step 805, a plurality of second grooves 204 each next to one of the first grooves 202 are defined. In the present embodiment, the masks 70 are removed after the second vertical separating process. Then in step 806, the second electrode layer 26 is deposited on the photoelectric conversion layer 24. A plurality of third grooves 206 are formed to penetrate through the second electrode layer 26 in step 807, wherein each of the third grooves 206 is formed next to one of the second grooves 204.

Then in step 808, a plurality of second traversing grooves 210 and 212 are formed, wherein each two of the second traversing grooves 210 and 212 are formed next to and on the opposite side of one of the first traversing grooves 200, as depicted in FIG. 7D. Further, in order to prevent the current leakages, an edge-cutting process 72 (shown as gray lines 72 in FIG. 7D) can be performed at the periphery of the glass substrate 20 to remove the thickness of each of the first electrode layer 22, the photoelectric conversion layer 24 and the second electrode layer 26, so as to isolate the thin film photoelectric conversion module 2.

It's noticed that all the separating processes described above can be implemented by, but not limited thereto, laser-scribing processes, chemical etching processes or mechanical separating processes. Further, the above-mentioned steps are not recited in the sequence in which the steps are performed. That is, unless the sequence of the steps is expressly indicated, the sequence of the steps is interchangeable, and all or part of the steps may be simultaneously, partially simultaneously, or sequentially performed.

The thin film photoelectric conversion module and the manufacturing process of the same disclosed herein is able to reduce the effect of the hot spot phenomenon.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A thin film photoelectric conversion module including a substrate and a plurality of photoelectric conversion cells formed on the substrate and connected to each other in series to form a series-connected array, comprising:
a plurality of first electrode rows extending along a current flow direction; and
a resistive material electrically connected to adjacent two of the first electrode rows, wherein the resistive material has an electrical resistivity no less than 10⁻⁹ ohm-cm, wherein when the resistive material is a material different from that of the first electrode rows, the resistive material makes adjacent two of the first electrode rows at least partially connected, and when the resistive material is a material the same as that of the first electrode rows, the resistive material makes adjacent two of the first electrode rows partially connected.

2. The thin film photoelectric conversion module of claim 1, wherein the resistive material comprises a material of a photoelectric conversion layer of the series-connected array.

3. The thin film photoelectric conversion module of claim 1, wherein the substrate is a transparent substrate, further comprises a plurality of opaque materials each deposited between the transparent substrate and the series-connected array.

4. The thin film photoelectric conversion module of claim 1, wherein the substrate is a transparent substrate, further comprises a plurality of opaque materials each deposited on a side of the transparent substrate opposite to the series-connected array.

5. A thin film photoelectric conversion module, comprising:
a first electrode layer formed on a substrate, wherein the first electrode layer comprises a plurality of first electrode rows extending along a current flow direction, a resistive material electrically connected to adjacent two of the first electrode rows and a plurality of first grooves separating the first electrode layer into a plurality of first electrode columns along a direction which crosses the current flow direction, the resistive material having an electrical resistivity no less than 10⁻⁹ ohm-cm;
at least one photoelectric conversion layer deposited on the first electrode layer, wherein the photoelectric conversion layer comprises a plurality of second grooves each formed next to one of the first grooves; and
a second electrode layer deposited on the photoelectric conversion layer, wherein the second electrode layer comprises a plurality of third grooves penetrating through the second electrode layer and each of the third grooves is formed next to one of the second grooves, wherein when the resistive material is a material different from that of the first electrode rows, the resistive material makes adjacent two of the first electrode rows at least partially connected, and when the resistive material is a material the same as that of the first electrode rows, the resistive material makes adjacent two of the first electrode rows partially connected.

6. The thin film photoelectric conversion module of claim 5, wherein the resistive material is substantially formed in a plurality of first traversing grooves separating the first electrode layer into the plurality of first electrode rows.

7. The thin film photoelectric conversion module of claim 6, wherein at least one second traversing groove is formed next to each one of the first traversing grooves and penetrating through the second electrode layer.

8. The thin film photoelectric conversion module of claim 6, wherein the resistive material comprises a material of the photoelectric conversion layer.

9. The thin film photoelectric conversion module of claim 6, wherein each of the plurality of second grooves is substantially discontinuous and comprises a plurality of non-groove parts located at the positions of intersections of the corresponding second groove and the first traversing groove.

10. The thin film photoelectric conversion module of claim 5, wherein the substrate is a transparent substrate, further comprises a plurality of opaque materials each deposited between the transparent substrate and the first electrode layer.

11. The thin film photoelectric conversion module of claim 5, wherein the substrate is a transparent substrate, further comprises a plurality of opaque materials each deposited on a side of the transparent substrate opposite to the first electrode layer.

12. A method to fabricate a thin film photoelectric conversion module including a substrate and a plurality of photoelectric conversion cells formed on the substrate and connected to each other in series to form a series-connected array, comprising the steps of:
defining a plurality of first traversing grooves in a first electrode layer of the series-connected array along a current flow direction, so as to separate the first electrode layer into a plurality of first electrode rows; and
forming a resistive material between adjacent two of the plurality of first electrode rows, wherein the resistive material has an electrical resistivity no less than 10⁻⁹ ohm-cm.

13. The method of claim 12, wherein the resistive material comprises a material of a photoelectric conversion layer of the series-connected array.

14. The method of claim 12, wherein the step of forming a plurality of photoelectric conversion cells further comprises a step of defining a plurality of discontinuous second grooves, wherein at least one of the plurality of the discontinuous second grooves has a plurality of non-groove parts located at the positions of intersections of the corresponding second grooves and the first traversing grooves.

15. The method of claim 14, wherein the step of defining the plurality of the discontinuous second grooves further comprises forming a photoelectric conversion layer on the first electrode layer; placing a plurality of masks on the photoelectric conversional layer, which are in alignment with positions of the first traversing grooves; defining a plurality of second grooves in the photoelectric conversion layer; and removing the masks.

16. The method of claim 14, wherein the step of defining the plurality of the discontinuous second grooves further comprises forming a photoelectric conversion layer on the first electrode layer; and performing a discontinuous separating process on the photoelectric conversional layer.

17. The method of claim 12, further comprises a step of defining at least one second traversing groove next to each one of the first traversing grooves and penetrating through a second electrode layer of the series-connected array.

18. The method of claim 12, further comprises a step of defining at least one second traversing groove next to each one of the first traversing grooves and penetrating through a second electrode layer and a photoelectric conversion layer of the series-connected array.

19. The method of claim 12, wherein the substrate is a transparent substrate, further comprises forming a plurality of opaque materials each deposited between the transparent substrate and the first electrode layer.

20. The method of claim 12, wherein the substrate is a transparent substrate, further comprises forming a plurality of opaque materials each deposited on a side of the transparent substrate opposite to the first electrode layer.
